(19) United States
(12) Patent Application Publication
(10) Pub. No.: US 2008/0254306 A1
(43) Pub. Date: Oct. 16, 2008

(54) METHOD OF MANUFACTURING ORGANIC LIGHT-EMITTING DEVICE AND ORGANIC LIGHT-EMITTING DEVICE MANUFACTURED USING THE METHOD

(76) Inventors: Yong-Tak Kim, Suwon-si (KR); Won-Jong Kim, Suwon-si (KR); Jin-Baek Choi, Suwon-si (KR); Jong-Hyuk Lee, Suwon-si (KR); Yoon-Hyeung Cho, Suwon-si (KR); Byoung-Duk Lee, Suwon-si (KR); Min-Ho Oh, Suwon-si (KR); So-Young Lee, Suwon-si (KR); Sun-Young Lee, Suwon-si (KR)

Correspondence Address: CHRISTIE, PARKER & HALE, LLP, PO BOX 7068, PASADENA, CA, 91109-7068, US

(21) Appl. No.: 12/025,603

(22) Filed: Feb. 4, 2008

(30) Foreign Application Priority Data
Apr. 10, 2007 (KR) 10-2007-0035172

(51) Int. Cl. H05B 33/24; C23C 4/00; B05D 5/12

(52) U.S. Cl. 428/457; 427/535

(57) ABSTRACT

Provided is a method of manufacturing an organic light-emitting device, the method including: forming an anode; forming an intermediate layer including an emission layer on the anode; and forming a cathode on the intermediate layer, wherein the forming the cathode includes: thermally depositing indium oxide with plasma generated in a chamber; and surface-treating with plasma an indium oxide layer formed by the thermal depositing of the indium oxide.

### CROSS-REFERENCE TO RELATED PATENT APPLICATION

This application claims priority to and the benefit of Korean Patent Application No. 10-2007-0035172, filed on Apr. 10, 2007, in the Korean Intellectual Property Office, the entire content of which is incorporated herein by reference.

### BACKGROUND OF THE INVENTION

1. Field of the Invention

The present invention relates to a method of manufacturing an organic light-emitting device and an organic light-emitting device manufactured using the method, and, more particularly, to a method of manufacturing an organic light-emitting device exhibiting a high light-coupling efficiency and an organic light-emitting device manufactured using the method.

2. Description of the Related Art

An organic light-emitting device includes an anode and a cathode facing each other, and an intermediate layer (including an emission layer) interposed between the anode and the cathode. The emission layer of the intermediate layer generates light using holes derived from the anode and electrons derived from the cathode, and the light generated from the emission layer is emitted through the anode or the cathode. Thus, an electrode through which light is emitted should have a high transmittance.

In a method of manufacturing organic light-emitting devices, a transparent electrode is formed of Indium Tin Oxide (ITO) or the like. That is, an anode is formed, an intermediate layer is formed on the anode, and a cathode is formed on the intermediate layer using ITO or the like. In organic light-emitting devices manufactured using this method, the cathode is formed using sputtering. An image of the cathode thus formed is shown in FIG. 1. However, when forming the cathode using sputtering, an intermediate layer disposed below the cathode is damaged during the sputtering process. In order to solve this problem, a method of forming a cathode using thermal deposition has been proposed. However, when forming a cathode using a thermal deposition process, the temperature of a substrate for manufacturing the organic light-emitting device reaches about 300° C. In such a high temperature environment, the intermediate layer may be damaged.

In order to solve this problem, a method of forming an anode using ITO or the like and forming a cathode as a reflective electrode on the anode has been proposed. Here, the anode is formed using sputtering, an intermediate layer is formed on the anode, and the reflective cathode is formed using deposition. However, in order to form the intermediate layer interposed between the anode and the cathode, a new material is required instead of a conventional intermediate layer forming material. The intermediate layer interposed between the anode and the cathode includes suitable various layers, such as an electron injection layer, an electron transport layer, a hole injection layer, a hole transport layer, and an emission layer. These layers are formed of materials having appropriate lowest unoccupied molecule orbital (LUMO) levels, considering the work functions of the anode and the cathode. However, currently available intermediate layer forming materials are adapted for an anode formed as a reflective metal electrode and a cathode formed as a transparent electrode. Thus, in order to form an anode using ITO or the like, a new intermediate layer forming material needs to be developed, instead of a conventional intermediate layer forming material which is adapted for the work function of a reflective anode and the work function of a cathode formed of ITO or the like.

In view of this problem, a method of forming a cathode as a thin metal double layer, instead of as a transparent electrode, as illustrated in FIG. 2, has been proposed. Referring to FIG. 2, a cathode 20 is a double layer including an Mg layer 21 and an Ag layer 23. In this case, the cathode 20 can have a transmittance as low as less than 50%, thus, providing a relatively high reflectance. As a result, a micro-cavity structure is formed such that reflection repeatedly occurs between an anode 10 formed as a reflective electrode and the cathode 20. Thus, in order to prevent (or reduce) the destructive interference of light, a distance t of an intermediate layer 30 between the anode 10 and the cathode 20 must be controlled.

### SUMMARY OF THE INVENTION

An aspect of an embodiment of the present invention is directed toward a method of manufacturing an organic light-emitting device exhibiting a high light-coupling efficiency by forming a transparent cathode having an absolute work function value similar to that of (or substantially the same as) a transparent cathode formed using a conventional sputtering process, without damaging an intermediate layer included in the organic light-emitting device, and an organic light-emitting device manufactured using the method.

An embodiment of the present invention provides a method of manufacturing an organic light-emitting device, the method including: forming an anode; forming an intermediate layer including an emission layer on the anode; and forming a cathode on the intermediate layer, wherein the forming the cathode includes: thermally depositing indium oxide in plasma generated in a chamber; and surface-treating with plasma an indium oxide layer formed by the thermal depositing of the indium oxide.

The surface treating the indium oxide layer with the plasma may include lowering an oxygen ratio in the indium oxide layer.

Another embodiment of the present invention provides an organic light-emitting device formed by utilizing a method including: forming an anode; forming an intermediate layer including an emission layer on the anode; and forming a cathode on the intermediate layer, wherein the forming the cathode includes: thermally depositing indium oxide in plasma generated in a chamber; and surface-treating with plasma an indium oxide layer formed by the thermal depositing of the indium oxide.

Another embodiment of the present invention provides a method of manufacturing an organic light-emitting device, the method including: forming an anode; forming an intermediate layer including an emission layer on the anode; and forming a cathode on the intermediate layer, wherein the forming the cathode includes: thermally depositing indium oxide, and at least one of a metal or a metal oxide to form a transparent conductive layer of indium oxide doped with the at least one of the metal or the metal oxide; and surface-treating with plasma the transparent conductive layer of the indium oxide doped with the at least one of the metal or the metal oxide formed by the thermal depositing of the indium oxide, and the at least one of the metal or the metal oxide.

The forming the cathode may include thermally depositing the indium oxide and the at least one of the metal or the metal oxide in plasma generated in a chamber to form the transparent conductive layer of the indium oxide doped with the at least one of the metal or the metal oxide.

The surface treating the transparent conductive layer with the plasma may include lowering an oxygen ratio in the transparent conductive layer.

An absolute work function value of the at least one of the metal or the metal oxide may be lower than that of the indium oxide.

The metal may include a material selected from the group consisting of ytterbium (Yb), calcium (Ca), magnesium (Mg), samarium (Sm), cesium (Cs), barium (Ba), strontium (Sr), yttrium (Y), lanthanum (La), and combinations thereof.

The metal oxide may include a material selected from the group consisting of strontium oxide, calcium oxide, cesium oxide, barium oxide, yttrium oxide, lanthanum oxide, and combinations thereof.

The at least one of the metal or the metal oxide utilized to form the transparent conductive layer may include both the metal and the metal oxide.

The forming the cathode may include thermally depositing the indium oxide, the metal, and the metal oxide with plasma generated in a chamber to form the transparent conductive layer of indium oxide doped with the metal and the metal oxide.

The surface treating the transparent conductive layer with the plasma may include lowering an oxygen ratio in the transparent conductive layer.

Absolute work function values of the metal and the metal oxide may be each lower than that of the indium oxide.

The metal may include a material selected from the group consisting of ytterbium (Yb), calcium (Ca), magnesium (Mg), samarium (Sm), cesium (Cs), barium (Ba), strontium (Sr), yttrium (Y), lanthanum (La), and combinations thereof.

The metal oxide may include a material selected from the group consisting of strontium oxide, calcium oxide, cesium oxide, barium oxide, yttrium oxide, lanthanum oxide, and combinations thereof.

Another embodiment of the present invention provides an organic light-emitting device formed utilizing a method including: forming an anode; forming an intermediate layer including an emission layer on the anode; and forming a cathode on the intermediate layer, wherein the forming the cathode includes: thermally depositing indium oxide, and at least one of a metal or a metal oxide to form a transparent conductive layer of indium oxide doped with the at least one of the metal or the metal oxide; and surface-treating with plasma the transparent conductive layer of the indium oxide doped with the at least one of the metal or the metal oxide formed by the thermal depositing of the indium oxide, and the at least one of the metal or the metal oxide.

The at least one of the metal or the metal oxide utilized to form the transparent conductive layer may include both the metal and the metal oxide.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is an image showing a cathode of an organic light-emitting device manufactured using a conventional method;

FIG. 2 is a schematic sectional view illustrating an organic light-emitting device manufactured using a conventional method;

FIG. 3 is a schematic sectional view illustrating an organic light-emitting device manufactured using a method according to an embodiment of the present invention;

FIG. 4 is an image showing a cathode of an organic light-emitting device manufactured using a method according to an embodiment of the present invention; and

FIG. 5 is a comparative graph illustrating electrical characteristics of organic light-emitting devices manufactured using a conventional method and a method according an embodiment of the present invention.

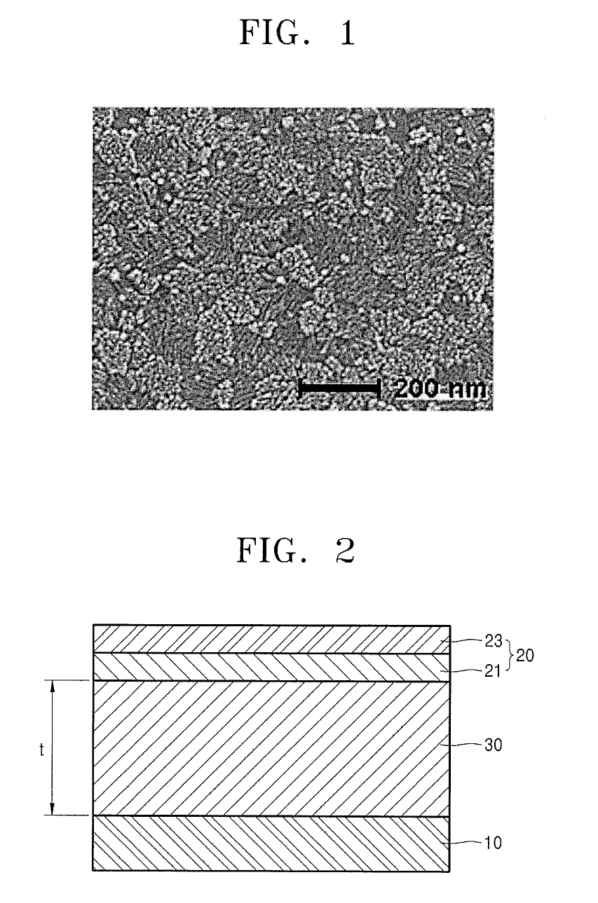

### DETAILED DESCRIPTION OF THE INVENTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

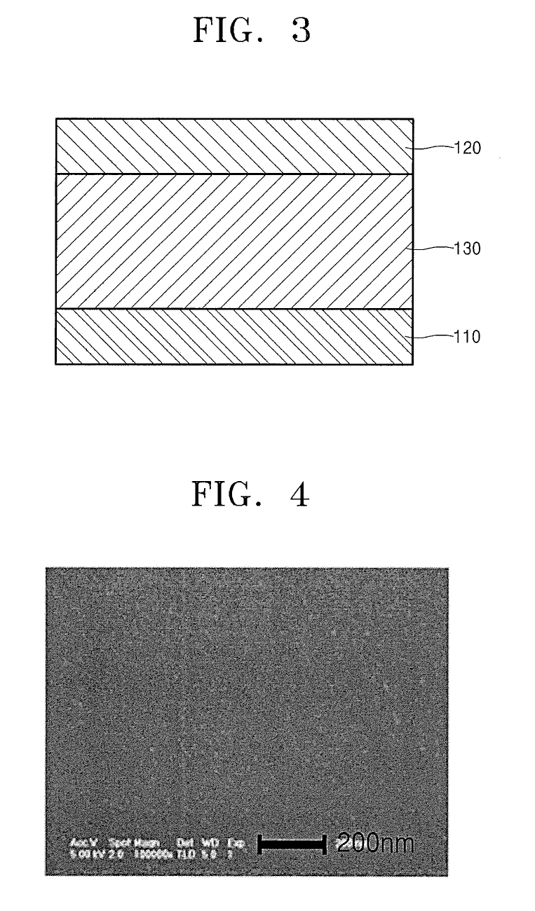

FIG. 3 is a schematic sectional view illustrating an organic light-emitting device manufactured using a method according to an embodiment of the present invention. Referring to FIG. 3, an anode 110 is formed, and an intermediate layer 130, including an emission layer, is formed on the anode 110. A cathode 120 is formed on the intermediate layer 130.

The anode 110 may be formed to have various suitable structures. The anode 110 may include a reflective layer formed of Ag, Mg, Al, Pt, Pd, Au, Ni, Nd, Ir, and/or Cr, and a layer formed of ITO, IZO, ZnO, and/or In₂O₃ on the reflective layer. The anode 110 may be formed using various suitable methods, such as deposition and/or sputtering. That is, since the anode 110 is formed before forming the intermediate layer 130, the anode 110 can be formed using any of a variety of suitable methods.

The intermediate layer 130 may be formed of a low molecular weight material or a polymer material. When the intermediate layer 130 is formed of a low molecular weight material, a hole injection layer (HIL), a hole transport layer (HTL), an emission layer (EML), an electron transport layer (ETL), an electron injection layer (EIL), etc. may be formed as a single-layered structure or a multi-layered composite structure. A low molecular weight material may be selected from various suitable materials, including copper phthalocyanine (CuPc), N,N′-di(naphthalene-1-yl)-N,N′-diphenyl-benzidine (NPB), tris-8-hydroxyquinoline aluminum (Alq3), etc. These layers may be formed using vacuum deposition or the like.

When the intermediate layer 130 is formed of a polymer material, it may be generally structured to include an HTL and an EML. Here, the HTL may be formed of polyethylenedioxythiophene (PEDOT), and the EML may be formed of a polymer material, such as a polyphenylenevinylene (PPV)-based and/or polyfluorene-based material. These layers may be formed using screen printing, inkjet printing, or the like.

The cathode 120 is formed as a transparent conductive layer. For this, the cathode 120 is formed of indium oxide. When a cathode is formed as a transparent conductive layer using a conventional sputtering process, an intermediate layer is damaged due to the characteristics of sputtering. Furthermore, when a cathode is formed using a conventional thermal deposition process, an intermediate layer is damaged due to high temperature during the thermal deposition. However, according an embodiment of the present invention, the cathode 120 is formed using a low-temperature thermal deposition process, thereby effectively preventing (or reducing) damage to the intermediate layer 130 and resulting in the manufacture of a high-quality organic light-emitting device.

When an electrode is formed using a conventional thermal deposition process, a temperature of a substrate for manufacturing an organic light-emitting device reaches about 300° C., thereby damaging an intermediate layer. According to an embodiment of the present invention, in order to lower a deposition temperature for forming the electrode, plasma is generated in a chamber for performing a deposition process, and in this state, indium oxide is thermally deposited. The plasma may be generated using an ion gun. When the cathode 120 is formed in the presence of plasma generated in the chamber, a material for forming the cathode 120 is ionized, and thus, the deposition can be effectively performed without raising the deposition temperature. As such, when the cathode 120 is thermally deposited in the presence of plasma generated in the chamber, the temperature of a substrate is merely raised to about 100° C., thus effectively preventing (or reducing) damage to the intermediate layer 130. In addition, the thermal deposition of the cathode 120, in the presence of plasma generated in the chamber, can improve the mobility characteristics of the cathode 120, thereby remarkably lowering the resistance of the cathode 120.

As described above, the intermediate layer 130 interposed between the anode 110 and the cathode 120 of the organic light-emitting device may include various suitable layers, such as an EIL, an ETL, an HIL, an HTL, and an EML. These layers are formed of materials having appropriate LUMO levels, considering the work functions of the anode 110 and the cathode 120. Thus, in order to utilize currently available intermediate layer forming materials, the work function of the cathode 120 should be similar to that of (or substantially the same as) a transparent cathode formed using a conventional sputtering process.

An absolute work function value of a transparent cathode formed using a conventional sputtering process is about 4.4 eV. However, when a cathode is deposited in the presence of plasma generated in a chamber, an absolute work function value of the cathode is about 5.0 eV, which is higher than 4.4 eV. Thus, according to an embodiment of the present invention, the cathode 120 is formed by thermally depositing indium oxide at a low temperature in the presence of plasma generated in a chamber, and surface-treating the indium oxide layer with the plasma in order to lower the absolute work function value of the indium oxide layer. The surface-treatment of the indium oxide layer with the plasma lowers the oxygen ratio of the indium oxide layer. When the oxygen ratio of the indium oxide layer is lowered, the absolute work function value of the indium oxide layer is gradually reduced to about 4.7 eV, which is substantially similar to that of a cathode formed using a conventional sputtering process. Thus, a currently available intermediate layer forming material can be utilized.

Characteristics of transparent cathodes formed to a thickness of 1,000 Å using indium oxide according to the above-described method are presented in Table 1 below.

TABLE 1

| | Argon | Oxygen | Resistance | Transmittance (%) | | | \|Work function\| |
|---|---|---|---|---|---|---|---|
| Sample No. | (sccm) | (sccm) | (Ωcm) | Blue light | Green light | Red light | (eV) |
| 1 | 10 | 20 | 500 | 95 | 93 | 88 | 5.1 |
| 2 | 10 | 10 | 9.1 | 95 | 90 | 86 | 5.0 |
| 3 | 10 | 7 | 2.9 | 94 | 87 | 86 | 4.7 |
| 4 | 10 | 5 | 5.0 | 85 | 81 | 84 | 5.0 |

As can be seen from Table 1, according to an embodiment of the present invention, the work function of a transparent cathode can be controlled by controlling the flow rate of oxygen. That is, for the cathodes of Samples 1-3, when indium oxide layers formed under oxygen flow rates of 20, 10, and 7 sccm, were plasma-treated with an ion gun, absolute work function values of the cathodes were controlled to be 5.1, 5.0, and 4.7 eV, respectively. For the cathodes of Sample 4, when the flow rate of oxygen was further reduced to 5 sccm, the cathodes exhibited an increased resistance, a decreased transmittance, and an increased absolute work function value. This shows that when an indium oxide layer is surface-treated under an oxygen flow of 5 sccm, an oxide content in the indium oxide layer reaches a saturation state.

The cathodes of Sample 3 exhibited an absolute work function value of 4.7 eV, which is similar to that of (or substantially the same as) a cathode formed using a conventional sputtering process. During formation of a cathode as described above, a temperature of a substrate is merely raised to about 100° C., thus substantially preventing damage to an intermediate layer, unlike a conventional thermal deposition process. Furthermore, a sputtering process is not involved in the formation of a cathode, thus substantially preventing damage to an intermediate layer, unlike a conventional cathode formation process. In addition, the transmittance of a cathode for blue, green, and red light is as high as about 85% or more, which is higher than that of a cathode formed as a metal double layer using a conventional method. Thus, it is possible to manufacture an organic light-emitting device without considering a distance between an anode and a cathode, which simplifies the manufacture of the organic light-emitting device.

In addition to the above-described embodiment of the present invention, a more efficient organic light-emitting device can be manufactured using a method according to another embodiment of the present invention. That is, a cathode may be formed as a transparent conductive layer in which indium oxide is doped with a metal and/or a metal oxide, instead of utilizing a simple indium oxide layer as described above. According to an embodiment of the present invention, a cathode forming material is deposited in the presence of plasma generated in a chamber in order to substantially lower the deposition temperature, and further, indium oxide and either a metal or a metal oxide are thermally co-deposited. Then, a layer formed by the deposition is surface-treated with plasma.

As described above, an intermediate layer interposed between an anode and a cathode includes various suitable layers, such as an EIL, an ETL, an HIL, and an HTL, in addition to an emission layer. These layers are formed of materials having appropriate LUMO levels considering the work functions of the anode and the cathode. Thus, in order to utilize currently available intermediate layer forming materials, the work function of the cathode should be similar to that of (or substantially the same as) a transparent cathode formed using a conventional sputtering process.

The absolute work function value of a transparent cathode formed using a conventional sputtering process is about 4.4 eV. According to an embodiment of the present invention, the absolute work function value of a cathode can be reduced to about 4.7 eV. According to another embodiment of the present invention, the absolute work function value of a cathode can be further reduced to less than about 4.7 eV. In order to lower the absolute work function value of a cathode, when forming the cathode, indium oxide and either a metal or a metal oxide are thermally co-deposited, instead of thermal deposition of only indium oxide. After the co-deposition of the metal or the metal oxide with the indium oxide is completed, the resultant transparent conductive layer is surface-treated with plasma to form a transparent cathode in which the indium oxide is doped with the metal or the metal oxide. A cathode formed as described above has an absolute work function value of about 4.4 eV, which is substantially similar to that of a cathode formed using a conventional sputtering process. Thus, a currently available intermediate layer forming material can be utilized.

As described above, a cathode is formed by thermally co-depositing a metal and/or a metal oxide with indium oxide. The metal may be ytterbium (Yb), calcium (Ca), magnesium (Mg), samarium (Sm), cesium (Cs), barium (Ba), strontium (Sr), yttrium (Y), and/or lanthanum (La). The metal oxide may be strontium oxide, calcium oxide, cesium oxide, barium oxide, yttrium oxide, and lanthanum oxide. The metal or the metal oxide may have a lower absolute work function value than that of the indium oxide. That is, by thermally co-depositing indium oxide with a metal and/or a metal oxide having a lower absolute work function value than the indium oxide, a transparent conductive layer in which the indium oxide is doped with the metal and/or the metal oxide is formed as a cathode. In this manner, the absolute work function value of the cathode can be controlled to be similar to that of (or substantially the same as) a cathode formed using a conventional sputtering process.

FIG. 4 is an image showing a cathode of an organic light-emitting device manufactured using the above-described method. Referring to FIG. 4, the cathode exhibits a smaller surface roughness and thus a more uniform surface morphology compared to a cathode formed using a conventional sputtering process (see FIG. 1).

A method of forming a cathode having the above-described characteristics, i.e., a method of forming a transparent conductive layer in which indium oxide is doped with a metal and/or a metal oxide, can be suitably modified. For example, a metal source and an indium source may be thermally deposited under an oxygen atmosphere. In this case, indium and a metal (e.g., a metal other than indium) are respectively converted to indium oxide and metal oxide (e.g., a metal oxide other than indium oxide) due to the oxygen atmosphere during the thermal deposition, thereby forming a cathode in which the indium oxide is doped with the metal oxide. Alternatively, a metal source and an indium oxide source may be thermally deposited under an argon atmosphere. Since argon is an inert gas that does not affect the composition of deposition materials, it is possible to form a cathode in which indium oxide is doped with a metal. Further, a cathode in which indium oxide is doped with metal oxide may also be formed by thermally depositing a metal oxide source and an indium oxide source under an argon atmosphere. Furthermore, a cathode in which indium oxide is doped with metal oxide may be formed by thermally depositing a metal oxide source and an indium source under an oxygen atmosphere. In this case, during the deposition, indium is oxidized to indium oxide. A cathode in which indium oxide is doped with metal oxide may also be formed by thermally depositing a metal oxide source and an indium oxide source under an oxygen atmosphere. In this case, oxygen is plasmatized by an ion gun or the like, thus lowering the deposition temperature and leading to a reduction in resistance of the cathode. In addition, a cathode may be formed by thermally depositing a metal source and an indium source under a mixed atmosphere of oxygen and argon, or thermally depositing a metal source and an indium oxide source under a mixed atmosphere of oxygen and argon.

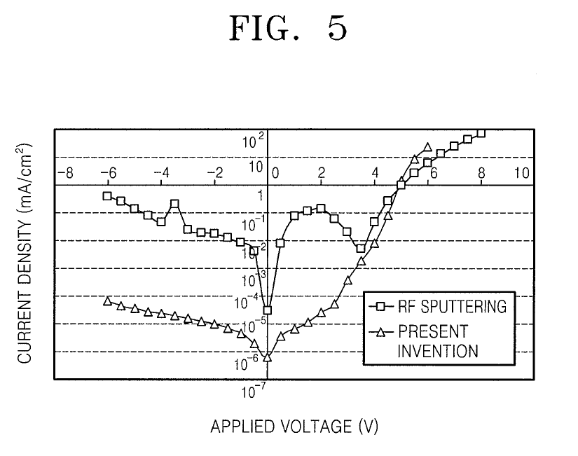

FIG. 5 is a comparative graph illustrating electrical characteristics of organic light-emitting devices manufactured using a conventional method and a method according an embodiment of the present invention. In detail, FIG. 5 illustrates a change in current density (ordinate axis or y-axis) with respect to an applied voltage (abscissa axis or x-axis) for an organic light-emitting device including a cathode formed using a conventional sputtering process and an organic light-emitting device including a cathode formed using a method according to an embodiment of the present invention. Referring to FIG. 5, in the organic light-emitting device including the cathode formed using the conventional sputtering process, due to damage to an intermediate layer caused during formation of the cathode, leakage current was caused when a reverse bias voltage was applied to the organic light-emitting device. On the other hand, in the organic light-emitting device manufactured according to the embodiment of the present invention, no damage to an intermediate layer was caused, and thus, even when a reverse bias voltage was applied to the organic light-emitting device, relatively little leakage current (10⁻⁵ mA) was caused.

The method of manufacturing the organic light-emitting device according to an above-described embodiment of the present invention has been illustrated in terms of formation of a cathode in which indium oxide is doped with either a metal or a metal oxide, but indium oxide may also be doped with both metal and metal oxide. For example, a transparent cathode in which indium oxide is doped with a metal and a metal oxide may be formed by thermally depositing a metal source, a metal oxide source, and an indium oxide source under an argon atmosphere and treating a surface of the deposited layer with plasma. Further, a cathode in which indium oxide is doped with a metal and a metal oxide may also be formed by thermally depositing a metal source and an indium source under an oxygen atmosphere. In this case, indium is oxidized to indium oxide, and the indium oxide is deposited. Some metals are oxidized to metal oxide, and the metal oxide is deposited. Some other metals are not oxidized and are deposited in a metal state. Furthermore, a cathode in which indium oxide is doped with a metal and a metal oxide may also be formed by thermally depositing a metal source and an indium oxide source under an oxygen atmosphere. In this case, some metals are oxidized to metal oxide, and the metal oxide is deposited. Some other metals are not oxidized and are deposited in a metal state. The deposition atmosphere employed is not limited to an oxygen atmosphere. That is, a cathode in which indium oxide is doped with a metal and a metal oxide may be formed by thermally depositing a metal source and an indium source under a mixed atmosphere of oxygen and argon, thermally depositing a metal source and an indium oxide source under a mixed atmosphere of oxygen and argon, or thermally depositing a metal source, a metal oxide source, and an indium oxide source under a mixed atmosphere of oxygen and argon.

As such, since a transparent cathode is formed by thermally co-depositing a metal and/or a metal oxide with indium oxide and treating a surface of the deposited layer with plasma, the formation of the cathode can be performed by low-temperature thermal deposition, and an absolute work function value of the cathode can be controlled to be similar to that of (or substantially the same as) a cathode formed using a conventional sputtering process.

As described above, in a method of manufacturing an organic light-emitting device and an organic light-emitting device manufactured using the method according to embodiments of the present invention, a transparent cathode having an absolute work function value similar to that of (or substantially the same as) a transparent cathode formed using a conventional sputtering process can be formed without damaging an intermediate layer of the organic light-emitting device, thereby improving the light-coupling efficiency of the organic light-emitting device.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method of manufacturing an organic light-emitting device, the method comprising:
forming an anode;
forming an intermediate layer comprising an emission layer on the anode; and
forming a cathode on the intermediate layer, wherein the forming the cathode comprises:
thermally depositing indium oxide in plasma generated in a chamber; and
surface-treating with plasma an indium oxide layer formed by the thermal depositing of the indium oxide.

2. The method of claim 1, wherein the surface treating the indium oxide layer with the plasma comprises lowering an oxygen ratio in the indium oxide layer.

3. An organic light-emitting device formed by utilizing a method comprising:
forming an anode;
forming an intermediate layer comprising an emission layer on the anode; and
forming a cathode on the intermediate layer, wherein the forming the cathode comprises:
thermally depositing indium oxide in plasma generated in a chamber; and
surface-treating with plasma an indium oxide layer formed by the thermal depositing of the indium oxide.

4. A method of manufacturing an organic light-emitting device, the method comprising:
forming an anode;
forming an intermediate layer comprising an emission layer on the anode; and
forming a cathode on the intermediate layer, wherein the forming the cathode comprises:
thermally depositing indium oxide, and at least one of a metal or a metal oxide to form a transparent conductive layer of indium oxide doped with the at least one of the metal or the metal oxide; and
surface-treating with plasma the transparent conductive layer of the indium oxide doped with the at least one of the metal or the metal oxide formed by the thermal depositing of the indium oxide, and the at least one of the metal or the metal oxide.

5. The method of claim 4, wherein the forming the cathode comprises thermally depositing the indium oxide and the at least one of the metal or the metal oxide in plasma generated in a chamber to form the transparent conductive layer of the indium oxide doped with the at least one of the metal or the metal oxide.

6. The method of claim 4, wherein the surface treating the transparent conductive layer with the plasma comprises lowering an oxygen ratio in the transparent conductive layer.

7. The method of claim 4, wherein an absolute work function value of the at least one of the metal or the metal oxide is lower than that of the indium oxide.

8. The method of claim 4, wherein the metal comprises a material selected from the group consisting of ytterbium (Yb), calcium (Ca), magnesium (Mg), samarium (Sm), cesium (Cs), barium (Ba), strontium (Sr), yttrium (Y), lanthanum (La), and combinations thereof.

9. The method of claim 4, wherein the metal oxide comprises a material selected from the group consisting of strontium oxide, calcium oxide, cesium oxide, barium oxide, yttrium oxide, lanthanum oxide, and combinations thereof.

10. The method of claim 4, wherein the at least one of the metal or the metal oxide utilized to form the transparent conductive layer comprises both the metal and the metal oxide.

11. The method of claim 10, wherein the forming the cathode comprises thermally depositing the indium oxide, the metal, and the metal oxide in plasma generated in a chamber to form the transparent conductive layer of the indium oxide doped with the metal and the metal oxide.

12. The method of claim 10, wherein the surface treating the transparent conductive layer with the plasma comprises lowering an oxygen ratio in the transparent conductive layer.

13. The method of claim 10, wherein absolute work function values of the metal and the metal oxide are each lower than that of the indium oxide.

14. The method of claim 10, wherein the metal comprises a material selected from the group consisting of ytterbium (Yb), calcium (Ca), magnesium (Mg), samarium (Sm), cesium (Cs), barium (Ba), strontium (Sr), yttrium (Y), lanthanum (La), and combinations thereof.

15. The method of claim 10, wherein the metal oxide comprises a material selected from the group consisting of strontium oxide, calcium oxide, cesium oxide, barium oxide, yttrium oxide, lanthanum oxide, and combinations thereof.

16. An organic light-emitting device formed utilizing a method comprising:
forming an anode;
forming an intermediate layer comprising an emission layer on the anode; and
forming a cathode on the intermediate layer, wherein the forming the cathode comprises:
thermally depositing indium oxide, and at least one of a metal or a metal oxide to form a transparent conductive layer of indium oxide doped with the at least one of the metal or the metal oxide; and
surface-treating with plasma the transparent conductive layer of the indium oxide doped with the at least one of the metal or the metal oxide formed by the thermal depositing of the indium oxide, and the at least one of the metal or the metal oxide.

17. The organic light-emitting device of claim 16, wherein the at least one of the metal or the metal oxide utilized to form the transparent conductive layer comprises both the metal and the metal oxide.
